(19) United States
(12) Patent Application Publication
(10) Pub. No.: US 2008/0062626 A1
(43) Pub. Date: Mar. 13, 2008

(54) Apparatus for Showing Moving Images in a Floor

(76) Inventors: Alec Leonard Ryman, Berkshire (GB); Nicole Anne Leader, Berkshire (GB)

Correspondence Address: Iandiorio & Teska, 260 Bear Hill Road, Waltham, MA, 02451-1018, US

(21) Appl. No.: 11/597,007

(22) PCT Filed: May 11, 2005
(86) PCT No.: PCT/GB05/01852

§ 371 Date: Nov. 16, 2006

(30) Foreign Application Priority Data
May 19, 2004 (GB) 0411142.3

(51) Int. Cl. H05K 5/02; H05K 7/20

(52) U.S. Cl. 361/681; 361/695

(57) ABSTRACT

Apparatus (2) for showing moving images in a floor, which apparatus (2) comprises a housing (4) for being mounted in the floor, a panel (6) which is positioned at an upper part (8) of the housing (4) and which is ale to be walked on, a screen (10) which is positioned beneath the panel (6) and on which the moving images are generated, cooling means (12) for cooling the screen (10) during use of the apparatus (2), vent means (14) for enabling air to circulate through the housing (4), and drainage means (16) for draining liquid entering the housing (4), the apparatus (2) being such that the panel (6) is a transparent panel (6) whereby the moving images on the screen (10) are able to be seen through the panel (6).

This invention relates to apparatus for showing moving images in a floor. The floor may be inside a building or outside a building.

Apparatus for showing moving images in a floor such for example as a pavement or a floor of a shopping mall is known. Such apparatus is able to be used for a wide variety of purposes including advertising and/or marketing and/or health and safety purposes.

It is an aim of the present invention to provide an improvement on the known apparatus.

Accordingly, in one non-limiting embodiment of the present invention there is provided apparatus for showing moving images in a floor, which apparatus comprises a housing for being mounted in the floor, a panel which is positioned at an upper part of the housing and which is able to be walked on, a screen which is positioned beneath the panel and on which the moving images are generated, cooling means for cooling the screen during use of the apparatus, vent means for enabling air to circulate through the housing, and drainage means for draining liquid entering the housing, the apparatus being such that the panel is a transparent panel whereby the moving images on the screen are able to be seen through the panel.

The apparatus of the present invention can be installed indoors or outdoors. The housing enables the apparatus to be mounted flush with the floor so that there is no possibility of a person tripping over the apparatus. The transparent panel protects the screen positioned beneath the panel. This enables the apparatus to be walked on without the screen becoming damaged. The cooling means advantageously cools the screen during use of the apparatus so that heat produced by the screen is controlled and is not allowed to become such that the screen would overheat and malfunction due to its position in the housing. The vent means enables air to circulate through the housing which assists in the operation of the cooling means. This provision of the vent means enables liquid to enter the housing but this is then able to be dealt with by the provision of the draining means. With the provision of the above features, the apparatus of the present invention is able easily to be installed as a compact unit which is robust in use and which is able to operate for an extended period of time without malfunction.

Preferably, the screen is a plasma screen, a liquid crystal display screen, a television screen, a light emitting diode screen, a laser-receiving screen, a projection television screen, a micro-projection television screen, or an organic light emitting diode screen. Other types of screens may be employed.

Usually, the cooling means will be positioned inside the housing. This enables the apparatus to be kept as compact as possible. If desired however the cooling means could be positioned outside the housing, for example on an outer face of the housing.

Preferably, the cooling means is a cooling fan. Usually only one cooling fan will be employed but more than one cooling fan may be employed if desired. Other types of cooling means may be employed.

Preferably, the transparent panel is a transparent reinforced glass panel. Other materials may be employed for the transparent panel so that, for example, the transparent panel may be made of a transparent plastics material. The transparent plastics material may be a clear polyacrylate material. Other transparent plastics materials may be employed.

Advantageously, the face of the panel that is able to be walked on is protected by an non-slip, non-scratch coating. The coating should be such that it does not impair the visibility of the moving images through the panel.

The apparatus may be one in which the housing has sides, a base and a top, and in which the panel is positioned in the top of the housing. The housing will usually be a rectilinear housing having four sides. The housing will thus normally be rectangular or square in plan. The housing may be of other shapes if desired.

The vent means may be positioned in the top of the housing.

The vent means may be a plurality of slots. Shapes other than slots may be employed.

The apparatus may be one in which the draining means includes channel means for collecting the liquid entering the housing, and pipe means for removing the liquid from the channel means. Advantageously, the channel means is a peripheral tray arrangement. The peripheral tray arrangement may be formed as part of the top of the housing.

The drainage means may include a pump for pumping the liquid out of the housing. Usually the pump will be positioned inside the housing. Such an arrangement enables the apparatus to be produced as compact as possible. If desired however the pump may be positioned outside the housing, for example on an outer face of the housing. Preferably, the pump is a bilge pump but other types of pumps may be employed.

The apparatus may include heating means for heating the screen at start-up conditions. This is because some screens will be such that they cannot be started up at low temperatures, for example as may occur if the apparatus of the present invention is installed outside in cold environments.

The heating means may be a heating fan. One or more of the heating fans may be employed. Other types of heating means may be employed.

When the heating means is a heating fan and when the cooling means is a cooling fan, then the heating fan may be part of a single unit containing the cooling fan, whereby the single unit only has one motor and fan arrangement, and whereby the single unit has switch means for causing a heating element to operate and thereby enable the unit to operate as a heating fan, or for causing the heating element not to operate and thereby enable the heating unit to operate as a cooling fan. Such an arrangement avoids duplication of parts and thereby enables the apparatus of the present invention to be produced in a very cost-effective manner.

An embodiment of the invention will now be described solely by way of example and with reference to the accompanying drawings in which:

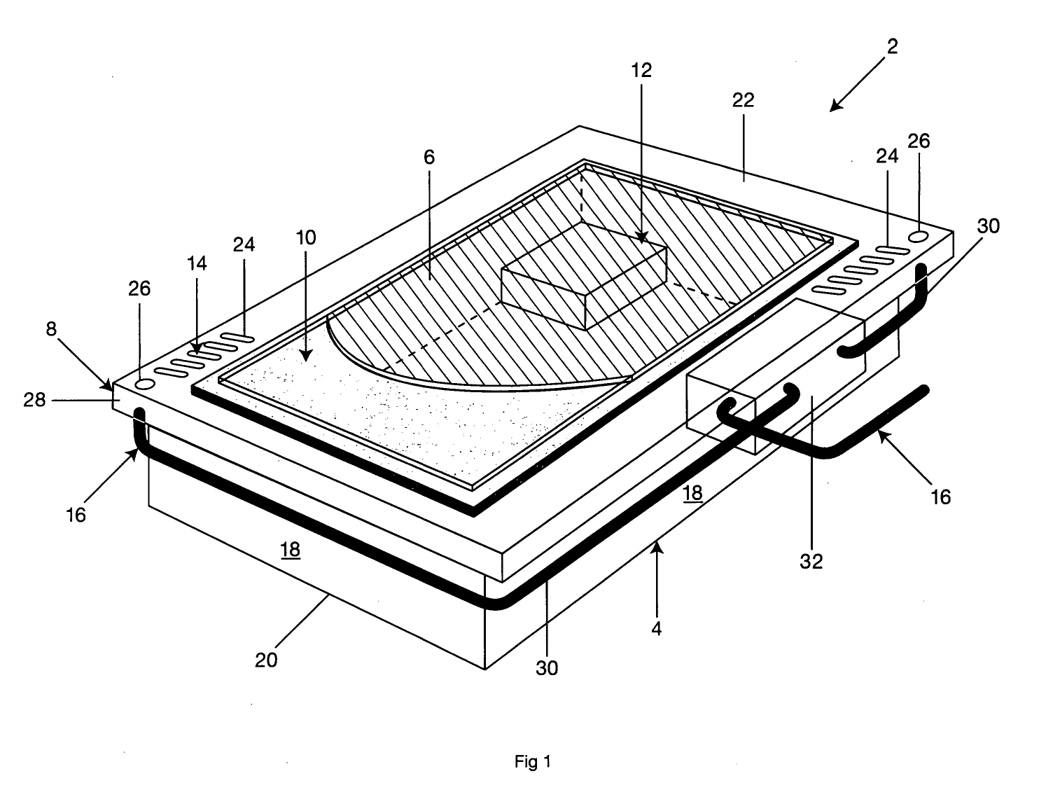

FIG. 1 is a schematic perspective view of apparatus for showing moving images in a floor;

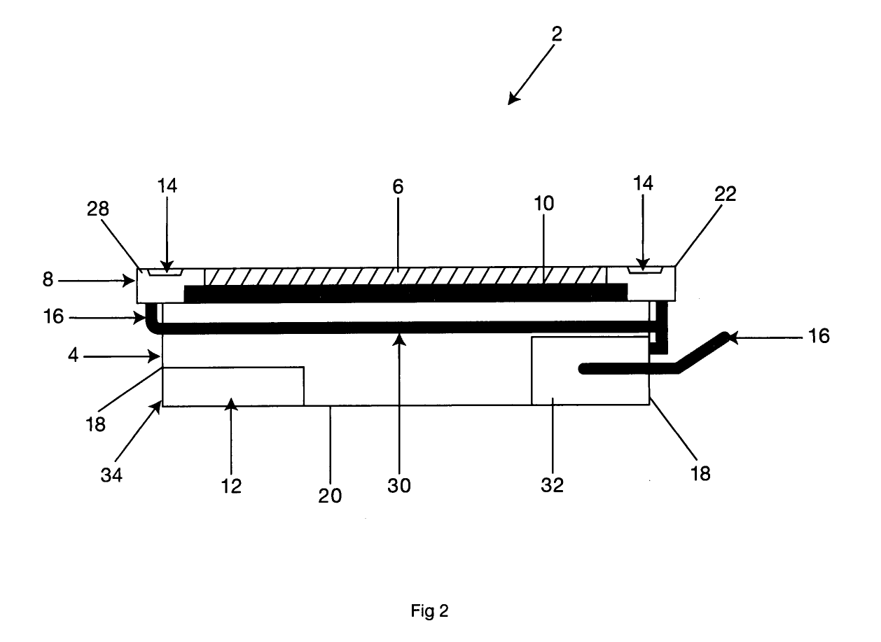

FIG. 2 is a section through the apparatus shown in FIG. 1; and

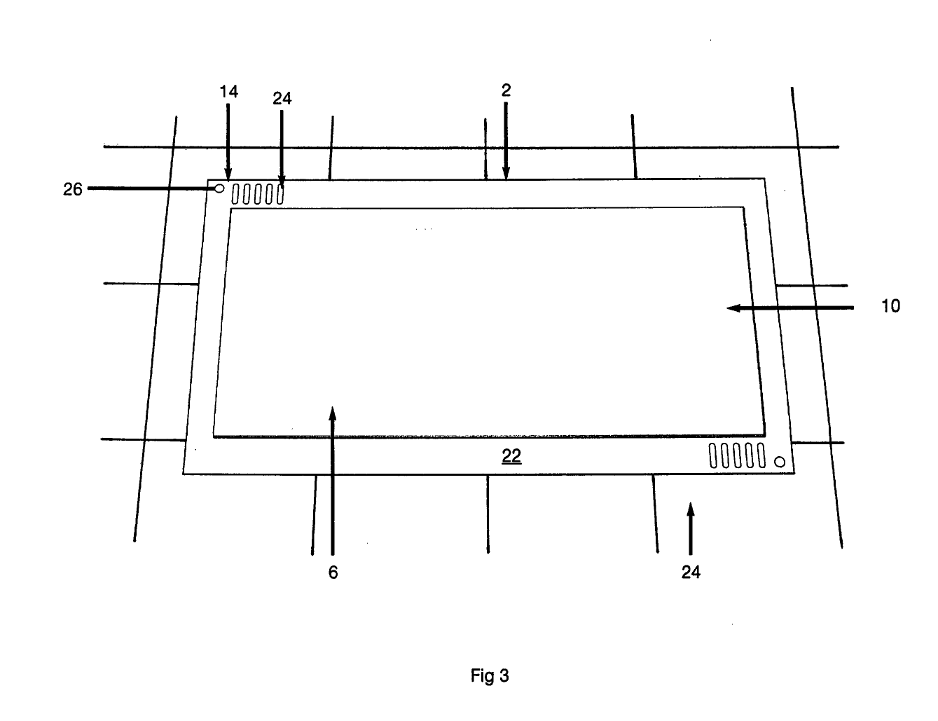

FIG. 3 shows the apparatus of FIG. 1 installed in a floor.

Referring to FIGS. 1 and 2, there is shown apparatus 2 for showing moving images in a floor. The apparatus 2 comprises a housing 4 for being mounted in the floor. The apparatus 2 also comprises a panel 6 which is positioned in an upper part 8 of the housing 4 and which is able to be walked on. A screen 10 is positioned beneath the panel 6. The moving images are generated on the screen 10.

The apparatus 2 further comprises cooling means 12 for cooling the screen 10 during use of the apparatus 2. Vent means 14 is provided for enabling air to circulate through the housing 4. Drainage means 16 is provided for draining liquid entering the housing 4, for example through the vent means 14.

The apparatus 2 is such that the panel 6 is transparent whereby the moving images on the screen 10 are able to be seen through the panel 6. The screen 10 is a plasma screen 10 or a liquid crystal display screen 10. The liquid crystal display screen 10 is sometimes known as a thin film transistor screen.

The cooling means 12 is a fan which is positioned inside the housing 4 as shown. The panel 6 is a transparent reinforced glass panel 6. The face of the panel 6 that is uppermost and that is able to be walked on is protected by a non-slip, non-scratch coating.

The housing 4 has sides 18, a base 20 and a top 22. The panel 6 is positioned in the top 22 of the housing 4. The housing 4 is a rectilinear housing having four sides. As shown in FIG. 1, the housing is rectangular in plan.

The vent means 14 is positioned in the top 22 of the housing 4. The vent means 14 is in the form of a plurality of elongate slots 24 arranged in two opposing corners of the housing 4. The vent means 14 also includes a circular aperture 26 as shown.

The drainage means 16 includes channel means 28 which is in the form of a peripheral tray arrangement in the upper part 8 of the housing 4. The drainage means 16 also includes pipe means 30 for removing the liquid from the channel means 28. The drainage means 16 still further includes a pump 32 for pumping the liquid out of the housing 4. The pump 32 is positioned inside the housing 4 as shown. The pump 32 is a bilge pump. For the purpose of draining water from the top of the housing 4, the vent means 14 also act as drainage holes. The illustrated vent means 14 can be any suitable and desired shaped holes, and the holes can be of the same shape or different shapes.

As mentioned above, the cooling means 12 is a cooling fan. The cooling fan has a motor and fan arrangement (not shown). The cooling means 12 in the form of the fan forms part of a single unit 34 which also is able to form heating means in the form of a heating fan. The heating fan is able to share the motor and fan arrangement of the cooling means 12. A heating element (not shown) is provided when the single unit 34 is to act as a heating unit. The heating unit is able to be engaged by switch means (not shown). More specifically, the switch means is able to cause the heating element to operate and thereby enable the single unit 34 to operate as a heating fan, or the switch means is able to cause the heating element not to operate and thereby enable the single unit 34 to operate as a cooling fan. The heating means may be required with some screens 10 which cannot be started up at low temperatures, for example as may be incurred when the apparatus 2 is installed outside in cold environments.

The apparatus 2 is able to be constructed as a compact piece of apparatus which is therefore easily to be able to be installed in a floor 36 as shown in FIG. 3.

Generally, the apparatus of the invention can be installed in any type of floor in any suitable and appropriate position, either inside buildings or outside buildings. Any suitable and appropriate type of moving images may be employed. The moving images can be for displaying commercial information and/or marketing information and/or health and safety information. Generally the moving images may be whatever is required and they can simply be displayed as people expect to see moving images on normal televisions.

It is to be appreciated that the embodiment of the invention described above with reference to the accompanying drawings has been given by way of example only and that modifications may be effected. Thus, for example, the housing 4 could be of a different shape to that shown. The panel 6 may be made of a transparent plastics material rather than transparent reinforced glass. The screen 10 may be a traditional television screen or other type of screen instead of a plasma screen or a liquid crystal display screen. Other types of cooling means and other types of drainage means to those shown may be employed.

1. Apparatus for showing moving images in a floor, which apparatus comprises a housing for being mounted in the floor, a panel which is positioned at an upper part of the housing and which is able to be walked on, a screen which is positioned beneath the panel and on which the moving images are generated, cooling means for cooling the screen during use of the apparatus, vent means for enabling air to circulate through the housing, and drainage means for draining liquid entering the housing, the apparatus being such that the panel is a transparent panel whereby the moving images on the screen are able to be seen through the panel.

2. Apparatus according to claim 1 in which the screen is a plasma screen, a liquid crystal display screen, a television screen, a light emitting diode screen, a laser-receiving screen, a projection television screen, a micro-projection television screen, or an organic light emitting diode screen.

3. Apparatus according to claim 1 in which the cooling means is positioned inside the housing.

4. Apparatus according to claim 1 in which the cooling means is a cooling fan.

5. Apparatus according to claim 1 in which the transparent panel is a transparent reinforced glass panel.

6. Apparatus according to claim 1 in which the face of the panel that is able to be walked on is protected by a non-slip, non-scratch coating.

7. Apparatus according to claim 1 in which the housing has sides, a base and a top, and in which the panel is positioned in the top of the housing.

8. Apparatus according to claim 7 in which the housing is a rectilinear housing having four sides.

9. Apparatus according to claim 7 in which the vent means is positioned in the top of the housing.

10. Apparatus according to claim 1 in which the vent means is a plurality of slots.

11. Apparatus according to claim 1 in which the drainage means includes channel means for collecting the liquid entering the housing, and pipe means for removing the liquid from the channel means.

12. Apparatus according to claim 11 in which the channel means is a peripheral tray arrangement.

13. Apparatus according to claim 1 in which the drainage means includes a pump for pumping the liquid out of the housing.

14. Apparatus according to claim 13 in which the pump is positioned inside the housing.

15. Apparatus according to claim 13 in which the pump is a bilge pump.

16. Apparatus according to claim 1 and including heating means for heating the screen at start-up conditions.

17. Apparatus according to claim 16 in which the heating means is a heating fan.

18. Apparatus according to claim 17 in which the heating fan is part of a single unit containing the cooling fan, whereby the single unit only has one motor and fan arrangement, and whereby the single unit has switch means for causing a heating element to operate and thereby enable the single unit to operate as a heating fan, or for causing the heating element not to operate and thereby enable the single unit to operate as a cooling fan.
